(19) United States
(12) Patent Application Publication
(10) Pub. No.: US 2020/0119209 A1
(43) Pub. Date: Apr. 16, 2020

(54) SHINGLED SOLAR CELL MODULE EMPLOYING CENTRALLY CONVERGED GRID LINE ELECTRODE

(71) Applicant: LONGI Solar Technology Co., Ltd, Shaanxi (CN)

(72) Inventors: Zhi ZHENG, Shanghai (CN); Jinfei MIAO, Jiangsu (CN)

(21) Appl. No.: 16/499,643

(22) PCT Filed: Apr. 19, 2017
(86) PCT No.: PCT/CN2017/081143

§ 371 Date: Sep. 30, 2019

(30) Foreign Application Priority Data
Mar. 30, 2017 (CN) 201710203952.7

(51) Int. Cl. H01L 31/0224; H01L 31/05

(52) U.S. Cl. CPC H01L 31/022433; H01L 31/0508; H01L 31/022441

(57) ABSTRACT

The disclosure provides a shingled solar cell module employing a centrally converged grid line electrode including main electrode points and secondary grid lines disposed on a cell slice, wherein the secondary grid line is a divergent pattern centering on the main electrode points, and converging currents to the main electrode points in a way of converging from periphery to center. According to the disclosure, areas of main grid line electrodes in front and back sides of a solar cell are reduced, thereby reducing the consumption of silver paste and conductive adhesive. Moreover, as a number and a cross-sectional area of the secondary grid lines are optimized, a photoelectric conversion efficiency of shingled cell slices with such patterns is improved in comparison with the conventional shingled cell slices with parallel secondary grid lines.

### FIELD OF TECHNOLOGY

The disclosure belongs to the field of solar cell technologies, and more particularly, to a shingled solar cell module employing a centrally converged grid line electrode.

### BACKGROUND

A solar cell is a device that converts light energy directly into direct current using a photovoltaic effect. According to different photoelectric conversion materials, the solar cells include monocrystalline silicon, polycrystalline silicon, amorphous silicon film, cadmium telluride film, copper indium gallium tin film, gallium arsenide, fuel sensitization, perovskite, shingled solar cells, and other types. The crystalline silicon solar cells are the most common solar cells, including monocrystalline silicon solar cells and polycrystalline silicon solar cells. The solar cell is usually in a sheet form. One side of the solar cell that can absorb light energy and convert it into electric energy is called a light absorbing side or a front side, and the other side is called a back side. For some solar cells, the back sides thereof may also absorb and convert light energy into electric energy. These solar cells are called double-sided cells.

A photovoltaic device that can be used for long-term use by electrically interconnecting a plurality of solar cells and then packaging the cells into a glass or organic polymer is called a photovoltaic module. A common method of interconnecting the cell slices in the crystalline silicon photovoltaic module is to arrange the cell slices in sequence, use a tin-coated solder strip containing a copper substrate as an interconnecting strip, weld one end of the interconnecting strip on a main grid line in a front side of a first cell slice, and weld the other end of the interconnecting strip on a grid line in a back side of an adjacent second cell slice. The two ends of a second interconnecting strip are respectively welded on a main grid line in a front side of the second cell slice and a back electrode of a third cell slice, and so on. In this way, all the cell slices are connected in series into one string.

A shingled solar cell module employs another technique for interconnecting cell slices. One side of a solar cell slice A is placed under another cell slice B, so that a main grid line electrode on a front side of the cell slice A and an electrode on a back side of the cell slice B are overlapped with each other. The two electrodes are conductively connected by using a conductive material. Meanwhile, the other side of the cell slice B is placed under a cell slice C, so that a main grid line electrode on a front side of the cell slice B and an electrode on a back side of the cell slice C are overlapped with each other, and the two electrodes are conductively connected by using a conductive material. In the same way, a plurality of cell slices can be sequentially interconnected to form a cell strings.

Electrode patterns on the front and back sides of the shingled cell slice are prepared by metallizing the surface of the solar cell. A common metallization method is to print a conductive paste containing silver particles on the surface of the cell by screen printing and sintering, and the electrode pattern can be changed by adjusting the screen graphics design of the screen printing.

In addition to an electrode region, a front surface of a crystalline silicon solar cell usually employs a silicon nitride film, and employs a screen printed aluminum paste in a back side usually. For some special solar cells, such as double-sided cells with both front and back side capable of absorbing light, surfaces of the regions other than the back electrode also employ a silicon nitride film instead of aluminum paste.

A conductive material between the electrodes of the cell slice in the shingled solar cell module includes a conductive adhesive, a solder strip or a solder paste, etc. Corresponding preparation methods should be selected according to the characteristics of the conductive material. For a cell string electrically interconnected by conductive adhesive, dispensing or printing can be used.

Main components of the conductive adhesive used in photovoltaic products include a resin matrix and a metal filler. The metal filler usually refers to silver or silver-containing particles. Compared with a common tin-coated copper strap, the conductive adhesive can not only form good mechanical adhesion and conductive connection with a silver paste, but also form good adhesion with other surfaces of the cell slice, such as silicon nitride film layer or silicon material.

Since silver is a precious metal, the costs of paste and conductive adhesive of a silver-containing solar cell are relatively high. At present, there are some technologies for preparing paste or conductive adhesive of solar cells by replacing silver with other metals, but the mainstream technologies in the market are still silver paste and silver conductive adhesive.

FIG. 1 is a design solution of a front electrode of a shingled cell. FIG. 2 is a design solution of a back electrode of the shingled cell. The shingled cell in FIG. 1 may be a large solar cell, and it may be cut into several pieces. As shown in FIG. 1, the shingled cell is cut for five pieces. In FIG. 1 and FIG. 2, the reference numeric 1 refers to a main grid line in a front side, 2 refers to a fine grid line in a front side, 3 refers to a main grid line in a back side. As shown in FIG. 1 and FIG. 2, each shingled cell slice will be cut into five small slices in subsequent steps, with one main grid line electrode on one side of a front side and one back electrode on the other side of a back side of each small slice. This technical solution is characterized in that all the main grid line electrodes and the back electrodes are made of silver paste in a solid rectangle. FIG. 3 is a schematic diagram of an interconnection solution between adjacent cells after the cells employing the technical solution are made into a photovoltaic module. The reference numeric 4 in FIG. 3 refers to a first sub-cell, 5 refers to a back electrode, 6 refers to conductive adhesive, 7 refers to a front electrode, 8 refers to a second sub-cell. As shown in FIG. 3, the first sub-cell 4 and the second sub-cell 8 are electrically communicated through conductive adhesive. The shingled module formed in FIG. 3, and the structure formed by sub-cells shingled with each other are called “shingled solar cell module” in the invention.

In the solution of the prior art, the consumption of the silver paste of the main grid line electrode is larger, and the consumption of the conductive adhesive is also larger, so the material cost is higher, and the photovoltaic power generation cost is higher.

Another disadvantage is that a length of the secondary grid line in the conventional solution is long, so the resistance loss of the secondary grid line is large, resulting in low photoelectric conversion efficiency of the cell.

In addition to the solutions mentioned above, there are other design solutions for the electrodes of the shingled cells. Each cell can be cut into two, three, four, six, seven or eight slices in addition to five small slices. For chamfered monocrystalline silicon cell slices, an electrode design decision similar to that of FIG. 1 and FIG. 2 is employed, and the chamfered and unchamfered slices are respectively formed into a cell string. For square monocrystalline silicon or polycrystalline silicon cell slices, the conventional solutions include the one in which all the front electrodes are located on a right side of the slice and all the back electrodes are located on a left side of the slice, i.e., a front electrode of a rightmost slice in FIG. 1 is moved to a right end of the slice, and a back electrode of the same slice is moved to a left end of the slice. What these electrode design solutions have in common is that all the front and back electrodes used are solid and successive silver electrodes in a rectangle pattern. Therefore, all these design solutions have the defects of large consumption of silver paste and high cost.

### SUMMARY

The disclosure aims to provide a shingled solar cell module employing a centrally converged grid line electrode, which is a high-efficiency low-cost electrode design solution for shingled cells, and the structure uses less silver paste and conductive adhesive than a traditional shingled solar cell module.

In order to achieve the above objects, a technical solution for preparation adopted by the disclosure is as follows.

A shingled solar cell module employing a centrally converged grid line electrode includes a plurality of sub-cells employing a centrally converged grid line electrode, wherein a front side of each sub-cell includes a plurality of front-side main electrode points and secondary grid lines; the plurality of front-side main electrode points are distributed along a long edge of a sub-cell slice, and the secondary grid line forms a divergent pattern centering on the front-side main electrode points, and converging currents to the front-side main electrode points in a way of converging from periphery to center; a back side of the sub-cell is provided with back-side main electrode points which is one-to-one corresponding to the front-side main electrode points; the front-side main electrode points and the back-side main electrode points of the same sub-cell are respectively distributed along two opposite long edges; and edges of adjacent sub-cells are overlapped, main electrode points of a first sub-cell and main electrode points in a back side of a second sub-cell are connected through conductive adhesive, and the first sub-cell and the second sub-cell are adhered and fixed through the conductive adhesive.

The secondary grid lines are divided into a plurality of secondary grid line groups distributed annularly from inside to outside by centering on the main electrode points, wherein an inner end of a first type secondary grid line of a first type secondary grid line group is connected with the main electrode points, and an outer end of the first type secondary grid line is connected with two second type secondary grid lines of a second type secondary grid line group, and the two second type secondary grid lines are connected with three type third secondary grid lines of a third type secondary grid line group, thus forming the divergent pattern by analogy in turn; and currents of every three third type secondary grid lines are converged to two second type secondary grid lines, currents of every two second type secondary grid lines are converged to one first type secondary grid line and then converged to the main electrode points.

Adjacent secondary grid line groups are also connected through arc-shaped secondary grid lines centering on the main electrode points.

The secondary grid lines are provided with different cross-sectional areas according to different currents passing by, and the secondary grid line with a larger current has a larger cross-sectional area; and the cross-sectional area is adjusted through a width and a height.

The secondary grid lines corresponding to adjacent main electrode points are cut off from extending after being intersected.

In different secondary grid line groups, a cross-sectional area of a corresponding grid line of the secondary grid line group close to the main electrode points is larger than a cross-sectional area of a corresponding grid line of the secondary grid line group far away from the main electrode points;

or, in the same secondary grid line group, a cross-sectional area of a grid line not connected with another secondary grid line group is smaller than a cross-sectional area of a grid line connected with another secondary grid line group;

or, the closer the same secondary grid line to the main electrode points, the larger a corresponding cross-sectional area of the grid line is.

The main electrode points in the front side and the main electrode points in the back side of the same sub-cell are respectively distributed along two opposite long edges; and the electrode points of two adjacent sub-cells are arranged at the same side or at different sides of the sub-cells.

The back side and the front side of the sub-cell have the same structure, both of which employ the centrally converged grid line electrode.

The back side of the sub-cell employs a structure that the back-side secondary grid lines is vertical to a main grid line in the back side; and the main grid line in the back side is connected with all the back-side main electrode points.

All or a part of an overlapped region between the first sub-cell (4) and the second sub-cell (8) except the area connected by the conductive adhesive (6) is adhered by non-conductive adhesive (11).

Compared with the prior art, the disclosure has the following effects.

According to the shingled solar cell module of the disclosure, the edges of the adjacent sub-cells are overlapped, the main electrode points of the first sub-cell and the main electrode points in the back side of the second sub-cell are electrically connected through the conductive adhesive. The first sub-cell and the second sub-cell are adhered together by the conductive adhesive meanwhile. The method for adhering and fixing is simple, and is convenient to operate. In particular, the centrally converged grid line electrode is employed in the front side or the back side of the solar shingled cell, and the secondary grid line with the electrode structure is a divergent pattern centering on the main electrode points, and converging currents to the main electrode points in a way of converging from periphery to center. The structure that the main grid and the secondary grid are vertical in the prior art is changed, and the structure can reduce the light shielding area of the electrode in the front side of the cell and improve the utilization of the light energy in the front side of the cell. The solar shingled cell introduces a front electrode winding technology into a back passivation cell technology, so that the two high-efficiency crystalline silicon cell technologies are better combined, achieving an effects obviously better than using one of the two technologies alone. The front side of the cell is improved by reducing the light shielding area of the electrode in the front side of the cell; and meanwhile, a passivation film on the back side of the cell preferably solves the leakage problem in metal winding. In addition, a local aluminum electrode on the back side of the cell is changed into an aluminum fine grid line, so that the cell has the function of generating electricity on both sides.

Further, in order to enhance an adhesion strength between the first sub-cell and the second sub-cell, all or a part of an overlapped region between the first sub-cell and the second sub-cell except the main electrode points may be adhered by non-conductive adhesive.

Further, a group of secondary grid lines converged to each main electrode point on the front side of the cell are divergent patterns centering on the main electrode point, and spacing between adjacent secondary grid lines increases with the increase of a length to the secondary grid lines. The number of the secondary grid lines is increased at a position far from the main electrode point, thereby reducing the spacing between the secondary grid lines at that position. The further the secondary grid lines is away from the main electrode point, the larger the number of the secondary grid lines is, therefore the circuit converging efficiency is provided.

Further, the cross-sectional area of the grid line may be increased in order to reduce resistance loss of the grid lines. To the secondary grid lines further away from the main electrode points, the cross-sectional area of the grid line may be relatively smaller because a current flowing through the sub-grid line is smaller. For the same kind of secondary grid lines, the cross-sectional areas of the grid lines are different due to different currents passing by. The same secondary grid line may also have different cross-sectional areas. The closer to the main electrode point, the greater the current passing by the secondary grid line is, and the greater the corresponding cross-sectional area of the grid line is. As the number and the cross-sectional area of the secondary grid lines are optimized, the photoelectric conversion efficiency of the shingled cell slices with such patterns is improved in comparison with the conventional shingled cell slices with parallel secondary grid lines.

Further, the areas of the main grid line electrodes in the front and back sides of the solar cell are reduced, thereby reducing the consumption of the silver paste and the conductive adhesive.

### BRIEF DESCRIPTION OF THE DRAWINGS

FIG. 1 is a schematic diagram of a front electrode of a current shingled cell ;

FIG. 2 is a schematic diagram of a back electrode of the current shingled cell;

FIG. 3 is a schematic diagram of a conductive adhesive pattern of the current shingled cell;

FIG. 4 is a schematic diagram of a front electrode pattern according to an embodiment of the present invention;

FIG. 5 is a schematic diagram of a back electrode pattern according to an embodiment of the present invention;

FIG. 6 is a diagram of a shingled cell structure formed by two sub-cells with conductive adhesive according to an embodiment of the present invention;

FIG. 7 is an exploded schematic diagram of a shingled cell structure formed by two sub-cells with conductive adhesive according to an embodiment of the present invention;

FIG. 8 is an exploded schematic diagram of a shingled cell structure with non-conductive adhesive according to an embodiment of the present invention;

FIG. 9 is a schematic diagram of an optimized secondary grid line of a cell slice according to an embodiment of the present invention;

FIG. 10 is a schematic diagram of an optimized secondary grid line of a cell slice according to an embodiment of the present invention;

FIG. 11 is a schematic diagram of an optimized secondary grid line of a cell slice according to an embodiment of the present invention;

FIG. 12 is a segmented schematic diagram of a back electrode according to an embodiment of the present invention;

FIG. 13 is a schematic diagram of a centrally converged grid line of a chamfered cell slice according to an embodiment of the present invention;

FIG. 14 is a schematic diagram of a grid line pattern in a front side of a shingled cell with six slices according to an embodiment of the present invention; and

FIG. 15 is a schematic diagram of a grid line pattern in a front side of a shingled cell with five slices according to an embodiment of the present invention.

1 refers to a main grid line in a front side, 2 refers to a fine grid line in a front side, 3 refers to a main grid line in a back side, 4 refers to a first sub-cell, 5 refers to a back electrode, 6 refers to conductive adhesive, 7 refers to a front electrode, 8 refers to a second sub-cell, 9 refers to a secondary grid line, 10 refers to a main electrode point in a front side, 11 refers to non-conductive adhesive, 12 refers to a first type secondary grid line, 13 refers to a second type secondary grid line, 14 refers to an arc-shaped secondary grid line, 15 refers to a third type secondary grid line, 16 refers to a chambered structure, 17 refers to a main electrode point in a back side, and 18 refers to a fine grid line in a back side, which is the secondary grid line in the back side.

### DESCRIPTION OF THE EMBODIMENTS

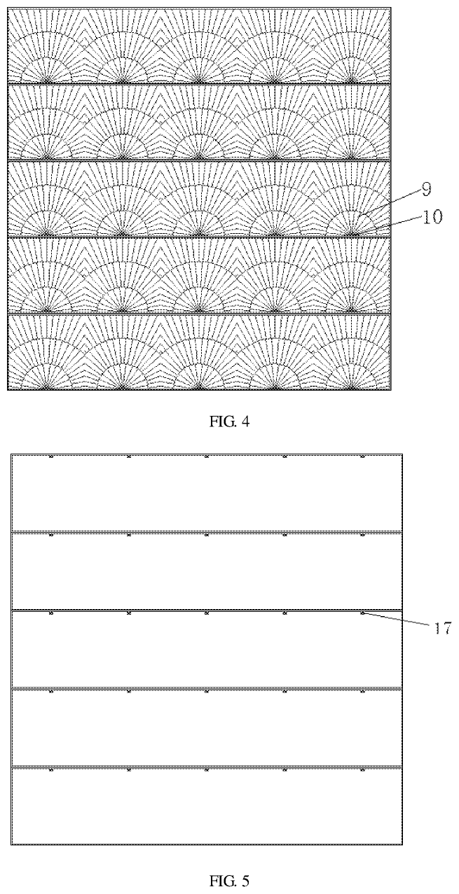

As shown in FIG. 4 and FIG. 5, a cell slice is divided into a plurality of sub-cells. Secondary grid lines on a front side of each sub-cell are divided into several groups. On the front side of the sub-cell, each group of secondary grid lines 9 converge currents to respective main electrode points 10 in a way of converging to center; and each main electrode point 10 is distributed along one long side of the sub-cell. A back electrode of the cell is corresponding to the main electrode points 10 in the front side one by one, which also presents in the form of main electrode points 17. The main electrode points 10 in the front side and the main electrode points 17 in the back side of the same sub-cell are respectively distributed along two opposite long edges.

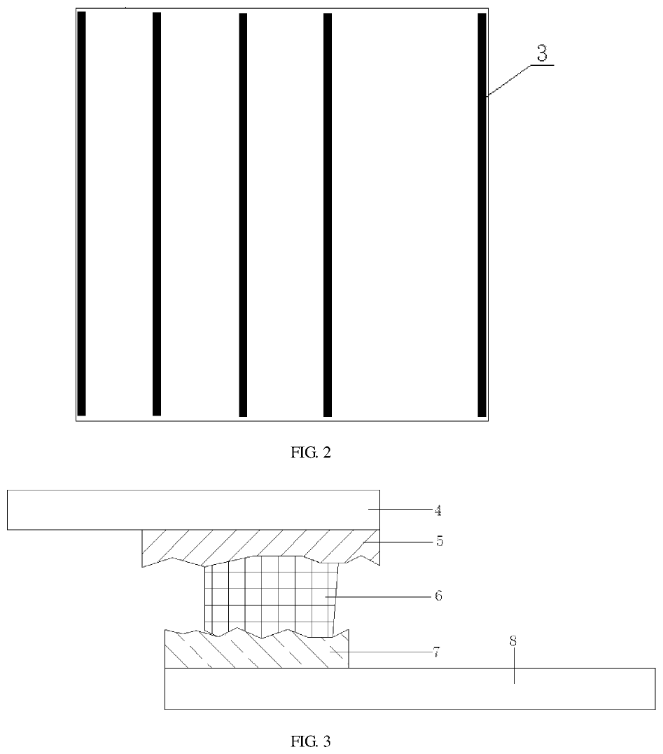

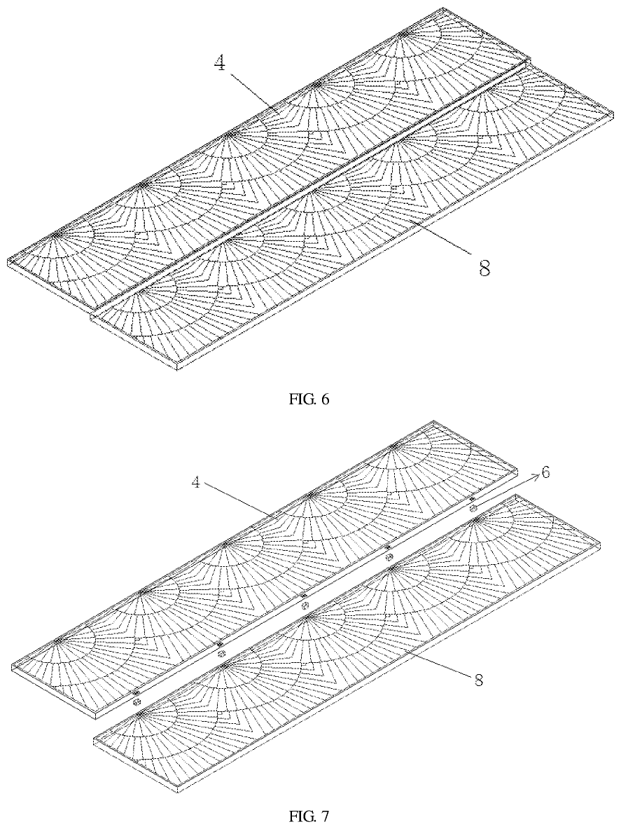

As shown in FIG. 6 and FIG. 7, edges of adjacent sub-cells in a shingled solar cell module are overlapped. Referring to FIG. 3 to FIG. 5,the main electrode points 10 in a front side of a first sub-cell 4 and main electrode points 17 in a back side of a second sub-cell 8 are electrically connected through conductive adhesive 6. By the electrical connection between the main electrode points, the first sub-cell 4 and the second sub-cell 8 are adhered together by the conductive adhesive 6 meanwhile.

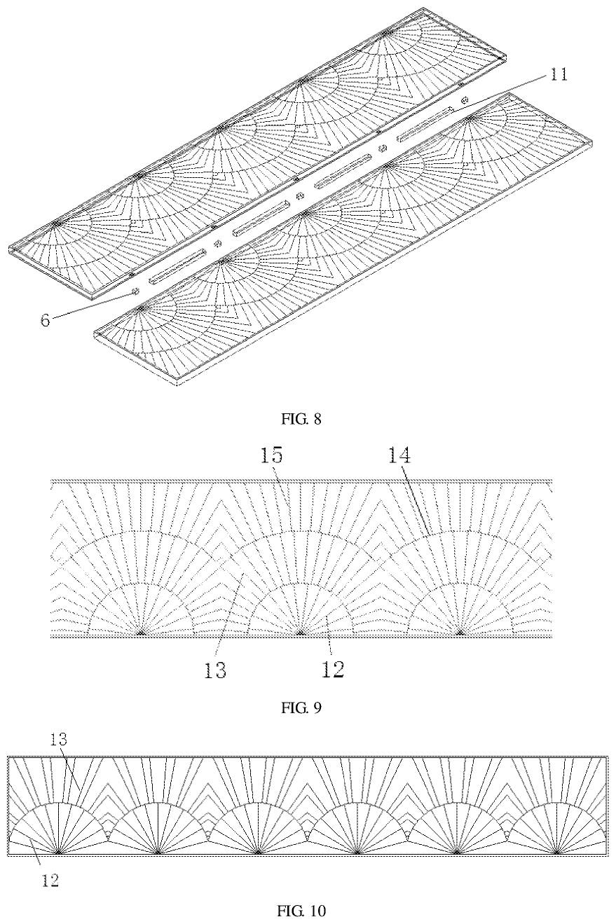

As shown in FIG. 8, in order to enhance an adhesion strength between the first sub-cell 4 and the second sub-cell 8, all or a part of an overlapped region between the first sub-cell 4 and the second sub-cell 8 except the main electrode points may be adhered by non-conductive adhesive 11.

Referring to FIG. 4, a group of secondary grid lines converged to each main electrode point on the front side of the cell is a divergent pattern centering on the main electrode point 10, and spacing between adjacent secondary grid lines increases with the increase of a length of the secondary grid lines 9. An optimized solution is to increase the amount of secondary grid lines at a position far from the main electrode point 10, thereby reducing the spacing between the secondary grid lines at that position. As shown in FIG. 9, the secondary grid lines in FIG. 9 are divided into four types, an amount of a first type secondary grid line 12 closest to the main electrode point is small, and an included angle between two adjacent secondary grid lines is large; an amount of a second type secondary grid lines 13 slightly away from the main electrode point 10 is large, and currents of every two second type secondary grid lines are converged to one first type secondary grid line 12; a density of a third type secondary grid lines 15 farthest from the main electrode point is higher, and current of every three third type secondary grid lines 15 are converged to two arc-shaped second type secondary grid lines 13. Adjacent secondary grid lines of the same kind are connected by an arc-shaped secondary grid line 14.

FIG. 10 and FIG. 11 are other optimized solutions for secondary grid lines. The secondary grid lines in FIG. 10 are divided into two types according to the distance to the main electrode point 10. Adjacent secondary grid lines FIG. 11 are directly interconnected to each other without passing through other secondary grid lines.

For the secondary grid line close to the main electrode point, the cross-sectional area of the secondary grid line may be larger in order to reduce the resistance loss of the grid line due to a larger current passing by. For the secondary grid line far from the main electrode point, the cross-sectional area of the grid line may be relatively smaller due to a smaller current passing by. The cross-sectional area of the grid line may be adjusted by changing a width or a height of the grid line. The solution of changing the width of the grid line is shown in FIG. 11. The width of the first type secondary grid line 12 is larger than the widths of the second type secondary grid line 13 and the third type secondary grid line 15.

For the same type of secondary grid lines, the cross-sectional areas of the grid lines may also be different due to different currents passing by. The secondary grid line with a larger current may have a larger cross-sectional area. As shown in FIG. 11, the grid lines have the same heights, but the current of the third type secondary grid line is converged on the second type secondary grid line 13 in the region above the main electrode point 10, so the width of the second type secondary grid line 13 in the region above the main electrode point may be larger than the width of the second type secondary grid lines 13 at left and right sides of the main electrode point 10 without being converged by the third type secondary grid lines.

The same secondary grid line 9 may also have different cross-sectional areas. The closer to the main electrode point 10, the greater the current passing by the secondary grid line is, and the greater the corresponding cross-sectional area of the grid line is.

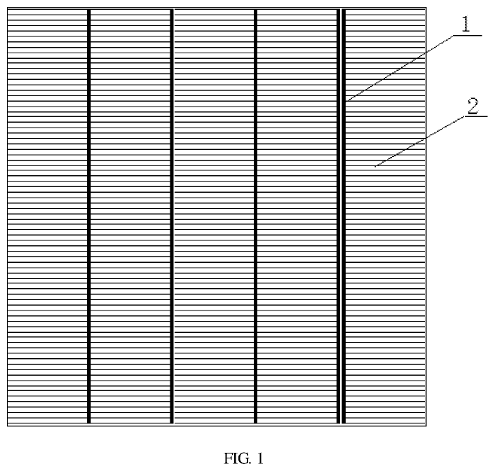

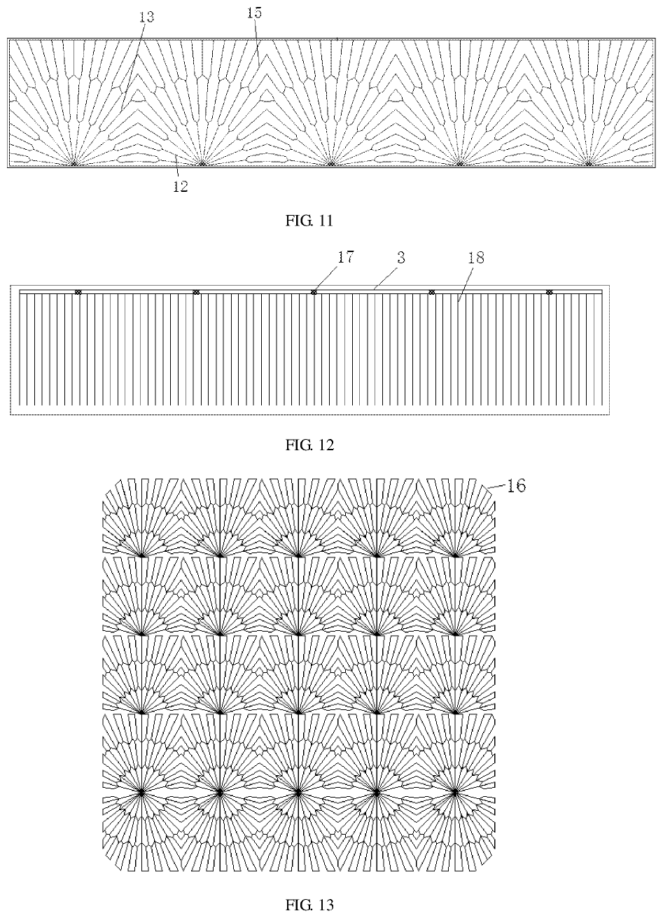

For a double-sided cell, a back side of the cell may employ a similar way of converging fine grid lines 18 to main electrode points 17 as a front side of the cell, or may employ other ways such as a conventional way of setting the fine grid lines 18 perpendicular to the main grid lines 3, similar to the grid line pattern in FIG. 1. In the latter way, other parts of a main grid line 3 in the back side, excluding main electrode points 17 in the back side corresponding to positions of main electrode points 10 in the front side, may adopt a hollowed-out pattern design, as shown in FIG. 12.

The above-mentioned design solution may also be applied to a chamfered cell slice, as shown in FIG. 13, which illustrates a design of a front electrode for a chamfered shingled cell slice. A pattern of the secondary grid line electrode at the chamfered portion is adjusted to form a corresponding chambered structure 16.

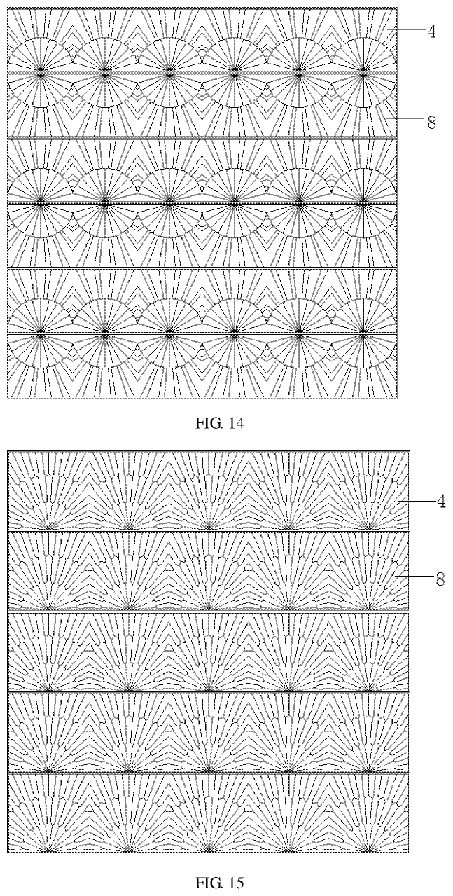

For the electrode pattern design of the shingled cells, besides the solution of cutting a monolithic cell into 5 slices, a design solution of cutting the monolithic cell into two, three, four, six, seven or eight slices may also be employed. FIG. 14 illustrates one of the solutions to cut the monolithic cell into six slices.

The main electrode points 10 on the same side of two adjacent sliced cells may either be adjacent, as shown in FIG. 14, or not adjacent, as shown in FIG. 4.

FIG. 15 illustrates a grid line pattern of a monolithic solar cell designed using the grid line pattern of the sliced cell in FIG. 11.

According to the design solution, the areas of the main grid line electrodes in the front and back sides of the solar cell are reduced, thereby reducing the consumption of the silver paste and the conductive adhesive. Moreover, as the number and the cross-sectional area of the secondary grid lines are optimized, the photoelectric conversion efficiency of the shingled cell slices with such patterns is improved in comparison with the conventional shingled cell slices with parallel secondary grid lines.

The disclosure may not only be applied to conventional crystalline silicon solar cells and PERC (Passivated Emitter and Rear Cell) solar cells, but also be applied to heterojunction cells, PERL(Passivated Emitter and Rear Locally-diffused) cells, PERT T (Passivated Emitter, Rear Totally-diffused cell) cells, TOPCon cells and other cell technologies.

A preparation method of the cell slice is the same as that of the conventional shingled cell slice, wherein silk screen printing is employed in the electrode grid lines, and screen printing plates for silk screen printing are manufactured according to the pattern in the disclosure.

When testing the efficiency of the cell slice, a front probe needs to contact the main electrode point, and a back probe or copper plate also needs to contact the main electrode point.

After the cell slice is prepared, the cell slice may be divided into several small slices by laser or mechanical scribing. The conductive adhesive is coated on the main electrode points by silk screen printing or dispensing, and then the cell slices are overlapped with each other to form a laminated structure.

The above are merely preferred embodiments of the disclosure, but are limited to the implementation scope of the disclosure. Any equivalent changes and modifications made in accordance with the contents of the patent scope of the disclosure shall fall within the technical scope of the disclosure.

1. A shingled solar cell module employing a centrally converged grid line electrode, comprising a plurality of sub-cells employing a centrally converged grid line electrode, wherein a front side of each sub-cell comprises a plurality of front-side main electrode points (10) and secondary grid lines (9); the plurality of front-side main electrode points (10) are distributed along a long edge of the sub-cell, and the secondary grid line (9) forms a divergent pattern centering on the front-side main electrode points (10), and converging currents to the front-side main electrode points (10); a back side of the sub-cell is provided with back-side main electrode points (17) which is one-to-one corresponding to the front-side main electrode points (10); the front-side main electrode points (10) and the back-side main electrode points (17) of the same sub-cell are respectively distributed along two opposite long edges; and edges of adjacent sub-cells are overlapped, the front-side main electrode points (10) of a first sub-cell (4) and the back-side main electrode points (17) of a second sub-cell (8) are connected through conductive adhesive (6), and the first sub-cell (4) and the second sub-cell (8) are adhered and fixed through the conductive adhesive (6).

2. The shingled solar cell module employing a centrally converged grid line electrode according to claim 1, wherein the secondary grid lines (9) are divided into a plurality of secondary grid line groups distributed annularly from inside to outside by centering on the main electrode points (10), an inner end of a first type secondary grid line (12) of a first type secondary grid line group is connected with the main electrode points (10), and an outer end of the first type secondary grid line (12) is connected with two second type secondary grid lines (1413) of a second type secondary grid line group, and the two second type secondary grid lines (1413) are connected with three third type secondary grid lines (15) of a third type secondary grid line group, thus forming the divergent pattern by analogy in turn; and currents of every three third secondary type grid lines (15) are converged to two second type secondary grid lines (13), currents of every two second type secondary grid lines (13) are converged to one first type secondary grid line (12) and then converged to the main electrode points (10).

3. The shingled solar cell module employing a centrally converged grid line electrode according to claim 2, wherein adjacent secondary grid line groups are also connected through arc-shaped secondary grid lines (14) centering on the main electrode points (10).

4. The shingled solar cell module employing a centrally converged grid line electrode according to claim 2, wherein the secondary grid lines (9) are provided with different cross-sectional areas according to different currents passing by, and the secondary grid line with a larger current has a larger cross-sectional area; and the cross-sectional area is adjusted through changing a width and a height of the secondary grid line.

5. The shingled solar cell module employing a centrally converged grid line electrode according to claim 4, wherein the secondary grid lines (9) corresponding to adjacent main electrode points (10) are cut off from extending after being intersected.

6. The shingled solar cell module employing a centrally converged grid line electrode according to claim 2, wherein in different secondary grid line groups, a cross-sectional area of a corresponding grid line of the secondary grid line group close to the main electrode points (10) is larger than a cross-sectional area of a corresponding grid line of the secondary grid line group far away from the main electrode points (10);
or, in the same secondary grid line group, a cross-sectional area of a grid line not connected with another secondary grid line group is smaller than a cross-sectional area of a grid line connected with another secondary grid line group;
or, the closer a secondary grid line to the main electrode points (10), the larger a corresponding cross-sectional area of the grid line of the secondary grid line is.

7. The shingled solar cell module employing a centrally converged grid line electrode according to claim 1, wherein the front-side main electrode points (10) and the back-side main electrode points (17) of the same sub-cell are respectively distributed along two opposite long edges; and the main electrode points (10) of two adjacent sub-cells are arranged at the same side or at different sides.

8. The shingled solar cell module employing a centrally converged grid line electrode according to claim 1, wherein the back side and the front side of the sub-cell have the same structure, both of which employ the centrally converged grid line electrode.

9. The shingled solar cell module employing a centrally converged grid line electrode according to claim 1, wherein the back side of the sub-cell employs a structure that the back-side secondary grid lines (18) is vertical to a main grid line (3) in the back side; and the main grid line (3) in the back side is connected with all the back-side main electrode points (17).

10. The shingled solar cell module employing a centrally converged grid line electrode according to claim 7, wherein all or a part of an overlapped region between the first sub-cell (4) and the second sub-cell (8) except the area connected by the conductive adhesive (6) is adhered by non-conductive adhesive (11).
